(19) United States
(12) Patent Application Publication
(10) Pub. No.: US 2014/0321081 A1
(43) Pub. Date: Oct. 30, 2014

(54) CIRCUIT BOARD MOUNTING APPARATUS

(71) Applicant: HON HAI PRECISION INDUSTRY CO., LTD., New Taipei (TW)

(72) Inventor: ZHENG-HENG SUN, New Taipei (TW)

(21) Appl. No.: 13/909,099

(22) Filed: Jun. 4, 2013

(30) Foreign Application Priority Data
Apr. 24, 2013 (CN) 2013101446301

(51) Int. Cl. H05K 7/14

(52) U.S. Cl. CPC H05K 7/1417
USPC 361/753

(57) ABSTRACT

A circuit board mounting apparatus includes a circuit board, a chassis, two mounting members, and two fasteners. A front side of the circuit board defines two positioning holes. The chassis includes a side plate defining two through holes. Two opposite ends of each mounting member define a latching slot and a mounting hole. A resilient arm extends toward the latching slot from each mounting member. The front side of the circuit board is inserted into the latching slots of the mounting members, and the resilient arms are engaged in the corresponding positioning holes of the circuit board. The fasteners extend through the through holes of the side plate, to be fastened into the mounting holes of the mounting members, to perpendicularly mount the circuit board to the side plate.

### BACKGROUND

1. Technical Field

The present disclosure relates to a circuit board mounting apparatus.

2. Description of Related Art

In electronic devices, circuit boards may be mounted inside the devices with a number of screws extending through the circuit board and engaging in a number of posts on a bottom wall of the chassis of the devices. However, manually fastening many screws in the chassis can be difficult and inconvenient because of the limited space for maneuvering.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of a first embodiment of a circuit board mounting apparatus, wherein the circuit board mounting apparatus includes two mounting members.

FIG. 2 is an enlarged view of one of the mounting members of FIG. 1 from another perspective.

FIG. 3 is an assembled, isometric view of FIG. 1 from another perspective.

FIG. 4 is an exploded, isometric view of a second embodiment of a circuit board mounting apparatus, wherein the circuit board mounting apparatus includes two mounting members.

FIG. 5 is an enlarged view of one of the mounting members of FIG. 4 from another perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

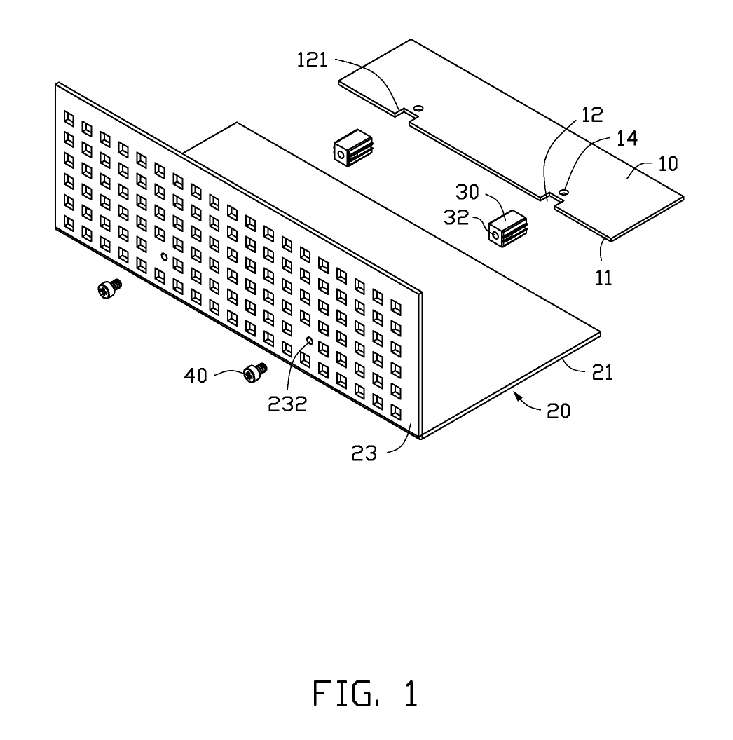

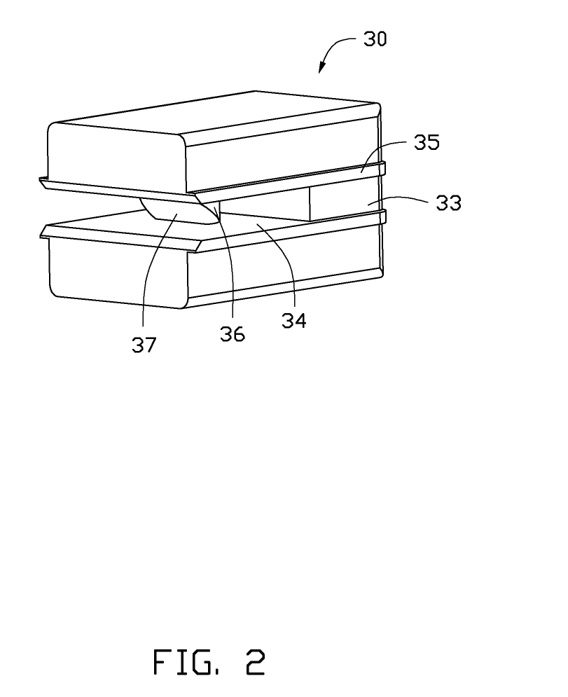

FIGS. 1 and 2 show a first embodiment of a circuit board mounting apparatus including a circuit board 10, a chassis 20, two mounting members 30, and two fasteners. In the embodiment, the fasteners are screws 40.

Two notches 12 are defined in a front side 11 of the circuit board 10. The circuit board 10 forms two sidewalls 121 bounding opposite sides of each notch 12. The circuit board 10 defines two positioning holes 14 located at rear sides of the notches 12.

The chassis 20 includes a bottom plate 21 and a side plate 23 extending up from the front side of the bottom plate 21. Two spaced through holes 232 are defined in the side plate 23 adjacent to the bottom plate 21.

A horizontally extending mounting hole 32 is defined in a front end of each mounting member 30. A rear end of each mounting member 30 horizontally defines a latching slot 34 extending through two opposite sides of the mounting member 30. Two spaced flanges 35 protrude out from each side of the mounting member 30, respectively above and below the latching slot 34, extending horizontally to the front end and the rear end of the mounting member 30. Two flanges 35 at each side of the mounting member 30 cooperatively bound a clamping slot 33. A resilient arm 36 perpendicularly extends down from a top surface bounding the latching slot 34. A rear side of a distal end of the resilient arm 36 defines a slanting guiding surface 37.

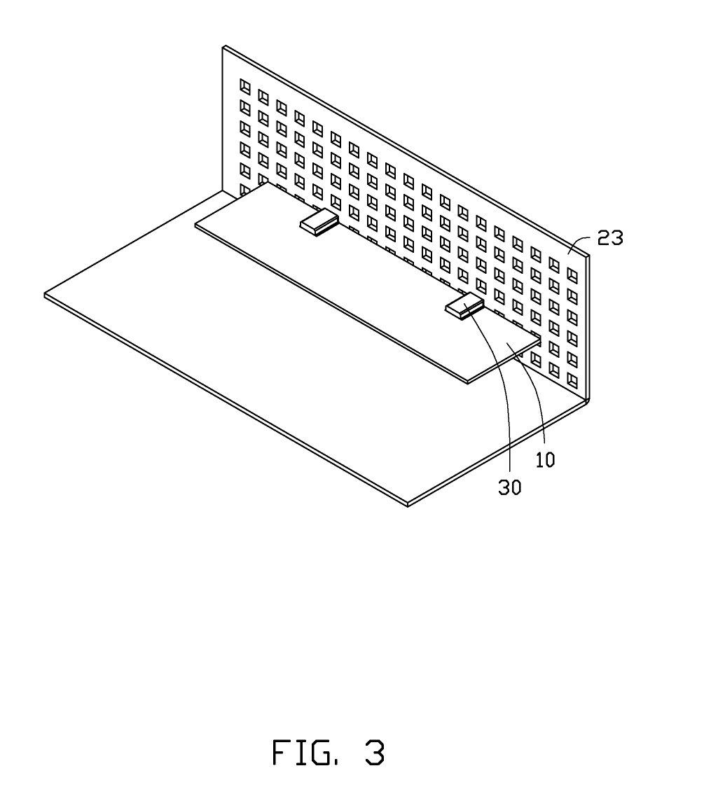

FIG. 3 shows that in assembly, the mounting members 30 are placed in front of the front side 11 of the circuit board 10, with the mounting members 30 aligning with the notches 12. The mounting members 30 are moved backward, to allow the sidewalls 121 bounding each slot 12 to engage in the clamping slots 33 of a corresponding one of the mounting members 30. The guiding surfaces 37 of the resilient arms 36 slidably abut the circuit board 10, deforming the resilient arms 36, until the distal ends of the resilient arms 36 align with the positioning holes 14 of the circuit board 10. The resilient arms 36 are restored to engage in the positioning holes 14. Thereby, the mounting members 30 are mounted to the front side 11 of the circuit board 10. The mounting holes 32 are parallel to the circuit board 10. The circuit board 10 is placed in the chassis 20, to allow the mounting holes 32 to align with the through holes 232. The screws 40 extend through the through holes 232 and engage in the corresponding mounting holes 32. Thereby, the circuit board 10 is perpendicularly mounted to the side plate 23.

Only two screws 40 need to be installed when mounting the circuit board 10, and the two screws 40 are installed from outside of the chassis 20, which is convenient.

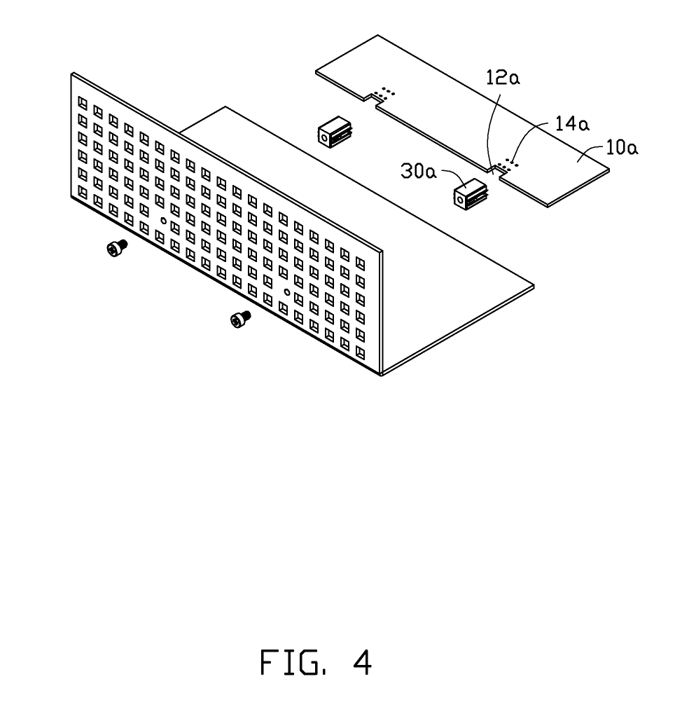

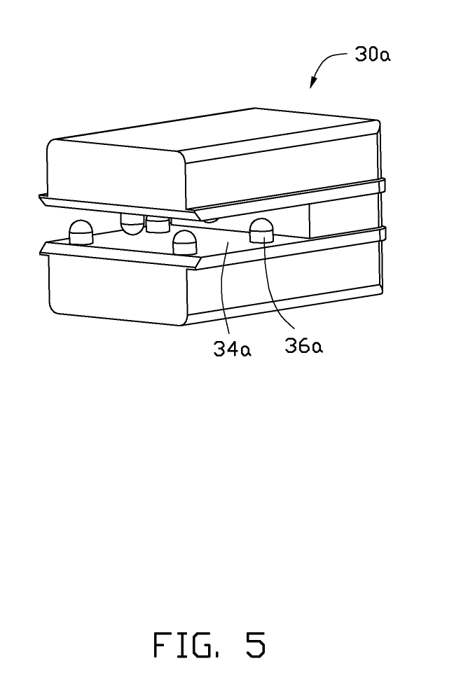

FIGS. 4 and 5 show a second embodiment of a circuit board mounting apparatus which is substantially similar to the first embodiment of the circuit board mounting apparatus. A circuit board 10a of the second embodiment of the circuit board mounting apparatus defines a plurality of positioning holes 14a located at a rear side of each notch 12a. A plurality of resilient arms 36a perpendicularly extends into a latching slot 34a from two opposite surfaces bounding the latching slot 34a of the second embodiment. A distal end of each resilient arm 36a is hemispherical. The resilient arms 36a can be engaged in the corresponding positioning holes 14a.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A circuit board mounting apparatus, comprising:
a circuit board defining two positioning holes in a front side of the circuit board;
a chassis comprising a side plate defining two through holes;
two mounting members; and
two fasteners;
wherein two opposite ends of each mounting member respectively define a latching slot and a mounting hole, a resilient arm extends into the latching slot from each mounting member, the front side of the circuit board is inserted into the latching slots of the mounting members, and the resilient arms are engaged in a corresponding one of the positioning holes of the circuit board, the fasteners extend through the through holes of the side plate from outside of the chassis, to be fastened into the mounting holes of the mounting members, to mount the circuit board to the side plate.

2. The circuit board mounting apparatus of claim 1, wherein the front side of the circuit board defines two notches one a side of the circuit board and respectively adjacent to the positioning holes, two flanges protrude out from each side surface of the mounting member, respectively above and below the latching slot, each two flanges at the same side surface of the mounting member cooperatively bound a clamping slot communicating with the latching slot, two opposite sidewalls bounding each notch of the circuit board are engaged in the clamping slots of a corresponding one of the mounting members.

3. The circuit board mounting apparatus of claim 1, wherein a distal end of each resilient arm defines a slanting guiding surface facing the circuit board.

4. The circuit board mounting apparatus of claim 1, wherein a distal end of each resilient arm is hemispherical.
